(19) United States
(12) Patent Application Publication
(10) Pub. No.: US 2026/0276676 A1
(43) Pub. Date: Sep. 17, 2026

(54) PROBE CARD AND METHOD FOR MANUFACTURING PROBE CARD

(71) Applicant: KABUSHIKI KAISHA NIHON MICRONICS, Tokyo (JP)

(72) Inventors: Toshinori OMORI, Musashino-shi (JP); Yuto NARA, Musashino-shi (JP); Masatoshi YOKOUCHI, Musashino-shi (JP); Tatsuya ITO, Musashino-shi (JP)

(73) Assignee: KABUSHIKI KAISHA NIHON MICRONICS, Tokyo (JP)

(21) Appl. No.: 19/560,696

(22) Filed: Mar. 9, 2026

(30) Foreign Application Priority Data
Mar. 17, 2025 (JP) 2025-041996

(51) Int. Cl. G01R 1/073; G01R 3/00

(52) U.S. Cl. CPC G01R 1/07357; G01R 1/07342; G01R 3/00

(57) ABSTRACT

A probe card includes a main board, a wiring board having a plurality of probes, a plurality of pogo pins electrically connecting the main board and the wiring board, and a pin holder disposed between the main board and the wiring board and having a plurality of guide holes which guide the plurality of pogo pins, in which the pin holder is formed from a ceramic holder having therein a plurality of conductor layers which are not electrically connected to each other.

### BACKGROUND OF THE INVENTION

### Field of the Invention

The present invention relates to a probe card and a method for manufacturing the probe card.

Priority is claimed on Japanese Patent Application No. 2025-041996 filed on Mar. 17, 2025, the content of which is incorporated herein by reference.

### Description of Related Art

Patent Document 1 (Japanese Patent No. 6609073) discloses a probe board having a plurality of electrical contacts that are respectively brought into electrical contact with a plurality of electrode terminals of an inspection target.

The probe board is electrically connected to a main board that transmits and receives electrical signals to and from a tester (inspection device) via an electrical connection unit. The electrical connection unit includes a plurality of pogo pins that connect the probe board and the main board, and a pin holder that guides the plurality of pogo pins.

### SUMMARY OF THE INVENTION

Incidentally, an inspection of an inspection target is performed under various temperature environments ranging from a low temperature to a high temperature, but in recent years, inspections have been conducted under more severe temperature environments. Since conventional pin holders are made of a resin and have a thermal expansion coefficient different from that of a probe board (wiring board), there has been a likelihood that, when thermal contraction or thermal expansion occurs, the pogo pins become displaced from contact points (pads) of the probe board, making it difficult to ensure electrical continuity.

The present invention has been made in view of the above-described problems, and an objective of the present invention is to provide a probe card capable of ensuring electrical continuity between a main board and a wiring board under various temperature environments, and a method for manufacturing the probe card.

A probe card according to one aspect of the present invention includes a main board, a wiring board having a plurality of probes, a plurality of pogo pins electrically connecting the main board and the wiring board, and a pin holder disposed between the main board and the wiring board and having a plurality of guide holes which guide the plurality of pogo pins, in which the pin holder is formed from a ceramic holder having therein a plurality of conductor layers which are not electrically connected to each other.

A method for manufacturing a probe card according to one aspect of the present invention is a method for manufacturing a probe card including a main board, a wiring board having a plurality of probes, a plurality of pogo pins electrically connecting the main board and the wiring board, and a pin holder disposed between the main board and the wiring board and having a plurality of guide holes which guide the plurality of pogo pins, in which the method includes: forming the pin holder from a ceramic holder having therein a plurality of conductor layers which are not electrically connected to each other.

According to one aspect of the present invention, it is possible to provide a probe card capable of ensuring electrical continuity between a main board and a wiring board under various temperature environments, and a method for manufacturing the probe card.

### BRIEF DESCRIPTION OF THE DRAWINGS

FIG. 1 is a schematic view illustrating a state in which a probe card according to a first embodiment is in use.

FIG. 2 is a cross-sectional configuration view of a pin holder according to the first embodiment.

FIG. 3 is a flowchart of a step for forming a ceramic holder according to the first embodiment.

FIG. 4 is a flowchart of a step for forming the ceramic holder according to one modified example of the first embodiment.

FIG. 5 is a schematic view illustrating a state in which a probe card according to a second embodiment is in use.

FIG. 6 is a cross-sectional configuration view of a top surface side of a wiring board according to the second embodiment.

FIG. 7 is a perspective view illustrating a state in which a second electronic component is attached to a block piece according to the second embodiment.

FIG. 8 is an explanatory view of a step for forming the block piece according to the second embodiment.

FIG. 9 is an explanatory view of a step for forming the block piece according to the second embodiment.

FIG. 10 is an explanatory view of a step for repairing an electronic component according to the second embodiment.

### DETAILED DESCRIPTION OF THE INVENTION

Hereinafter, an embodiment of the present invention will be described on the basis of the drawings. However, the embodiment described below is intended to exemplify apparatuses and methods for embodying the technical ideas of this invention, and the embodiment of the invention is not intended to limit materials, shapes, structures, arrangements, and the like of the components to those described below.

### First Embodiment

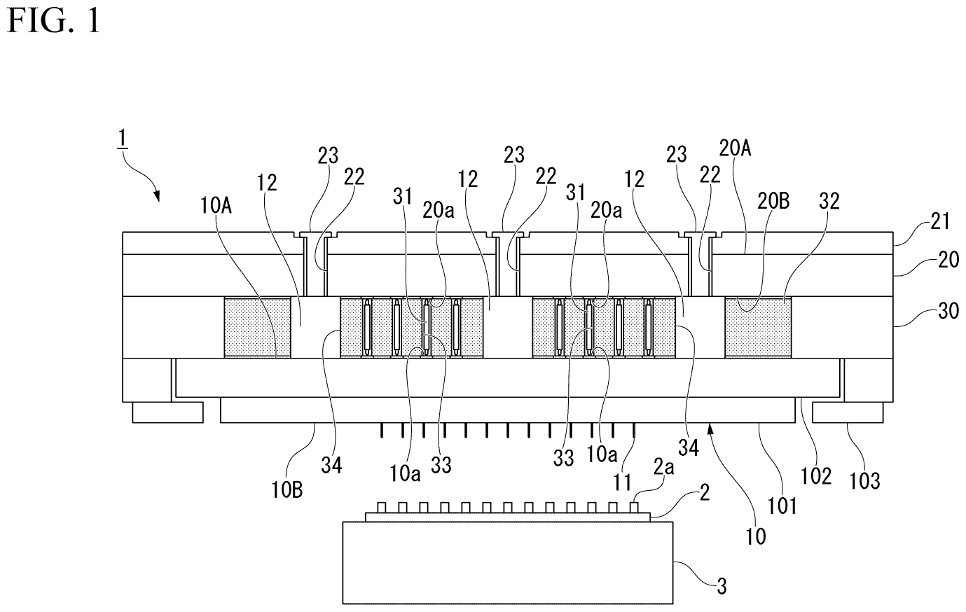

FIG. 1 is a schematic view illustrating a state in which a probe card 1 according to a first embodiment is in use. The probe card 1 illustrated in FIG. 1 is attached to an inspection device (such as a tester) (not illustrated), and inspects, for example, a semiconductor integrated circuit (not illustrated) formed on an inspection target 2 by bringing a probe 11 into contact with a pad 2a of the inspection target 2 such as a wafer.

The inspection target 2 is placed on an upper surface of a chuck top 3. The chuck top 3 is movable in a planar direction along a horizontal plane and in a vertical direction perpendicular to the horizontal plane, and furthermore is rotatable in a θ direction around the vertical axis. When an inspection of the inspection target 2 is performed, the chuck top 3 is raised or lowered in the vertical direction to bring the pad 2a of the inspection target 2 into electrical contact with a distal end part of the probe 11.

The probe card 1 includes a wiring board 10 (space transformer), a main board 20 (printed circuit board), and a connection unit 30 disposed between the wiring board 10 and the main board 20. A large number of probes 11 and other components (not illustrated) are mounted on a bottom surface 10B of the wiring board 10. A large number of anchors 12 and other components (not illustrated) are mounted on a top surface 10A of the wiring board 10.

The wiring board 10 includes a multilayer board 101 and a ceramic plate 102. The multilayer board 101 is formed, for example, by laminating boards made of a synthetic resin member such as polyimide, and has a wiring path (not illustrated) formed therein. An upper end of the wiring path of the multilayer board 101 is electrically connected to a lower end of a conductive path (not illustrated) of the ceramic plate 102, and the lower end of the wiring path is electrically connected to the probe 11.

The ceramic plate 102 has the conductive path (not illustrated) formed therein to penetrate therethrough in a thickness direction. An upper end of the conductive path of the ceramic plate 102 is electrically connected to a pad 10a formed on the top surface 10A. A lower end of a pogo pin 31 guided by a pin holder 32 of the connection unit 30 is in contact with the pad 10a.

Also, the plurality of anchors 12 fixed to a reinforcing plate 21 (stiffener) provided on an upper surface of the main board 20 are provided on the top surface 10A. The pin holder 32 has an insertion hole 34 extending therethrough in a thickness direction, and the anchor 12 is inserted and disposed in the insertion hole 34. An outer circumferential edge of the ceramic plate 102 is supported from the bottom surface 10B side by an annular board frame 103 in a plan view.

The main board 20 is formed of, for example, a resin material such as polyimide. An electrode terminal (not illustrated) for electrical connection to the inspection device (tester) (not illustrated) is provided on the upper surface of the main board 20. Also, a pad 20a with which an upper end of the pogo pin 31 is in contact is formed on a lower surface of the main board 20, and the main board 20 is electrically connected to the wiring board 10 via the pad 20a and the pogo pin 31. Thereby, the inspection target 2, the wiring board 10, the main board 20, and the inspection device (not illustrated) are electrically connected.

The reinforcing plate 21 for suppressing deformation (for example, bending or the like) of the main board 20 is attached to the upper surface of the main board 20. The main board 20 and the reinforcing plate 21 have through holes 22 extending therethrough in the thickness direction. The through holes 22 are formed in a number and disposition corresponding to the anchors 12 of the wiring board 10. A spacer 23 is inserted into the through hole 22 from the reinforcing plate 21 side. The spacer 23 is engaged with an upper end opening edge of the through hole 22, and a lower end part thereof is fixed (screwed) to the anchor 12. Thereby, the wiring board 10 and the main board 20 maintain a certain distance therebetween with the connection unit 30 interposed therebetween.

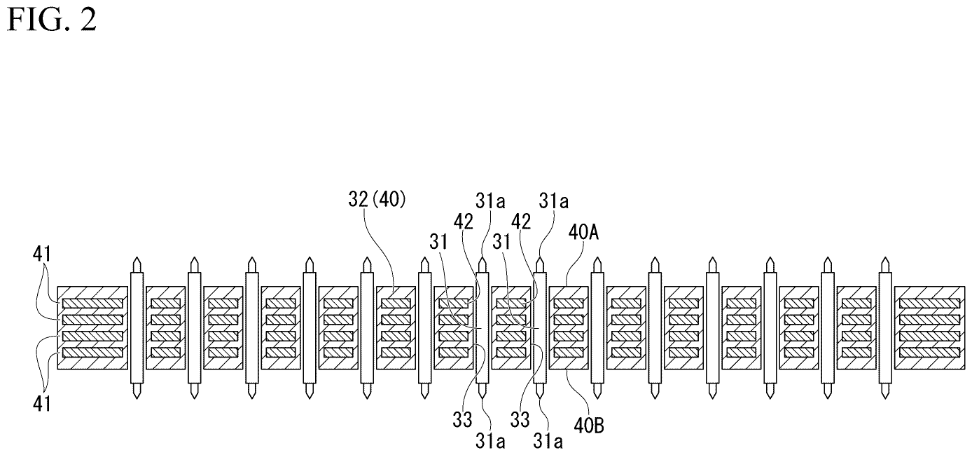

FIG. 2 is a cross-sectional configuration view of the pin holder 32 according to the first embodiment.

As illustrated in FIG. 2, the pin holder 32 is formed from a ceramic holder 40 having therein a plurality of conductor layers 41 that are not electrically connected to each other. The pin holder 32 is formed in a plate shape and has a plurality of guide holes 33 that guide a plurality of pogo pins 31 between the wiring board 10 and the main board 20. The guide hole 33 is formed linearly through the pin holder 32 in a thickness direction from an upper surface 40A to a lower surface 40B.

The pogo pin 31 includes a tubular body, a coil spring (not illustrated) housed inside the tubular body, and a pin body 31a that protrudes from and retracts into an end part of the tubular body by the coil spring. A pair of pin bodies 31a are provided and are configured to protrude from and retract into each of an upper end opening and a lower end opening of the tubular body. The pogo pin 31 is not tightly fitted in the guide hole 33, and is guided with a minute clearance formed between itself and an inner wall surface of the guide hole 33. That is, the pogo pin 31 is loosely fitted in the guide hole 33.

The pin holder 32 is formed from the ceramic holder 40 having the plurality of conductor layers 41 therein. The pin holder 32 is a laminate in which the plurality of conductor layers 41 (conductors) and a plurality of ceramic layers (insulators) are alternately laminated. The pin holder 32 is formed by laminating green sheets on which the conductor layers 41 are formed and firing the laminated green sheets, as will be described later. For this reason, when viewed as a component, although boundaries of the ceramic layers are clearly illustrated in FIG. 2, it may be difficult to distinguish the boundaries of the ceramic layers in actual samples.

The plurality of conductor layers 41 are laminated inside the pin holder 32 at intervals in the plate thickness direction. The plurality of conductor layers 41 are each covered with a ceramic layer (insulator) and are not electrically connected to each other. That is, the pin holder 32 is not provided with a through via or the like, and the conductor layers 41 adjacent to each other in the plate thickness direction are electrically insulated from each other. The plurality of conductor layers 41 each have a solid pattern in which openings 42 are formed at positions corresponding to the plurality of guide holes 33. The plurality of conductor layers 41 improve thermal diffusivity and heat dissipation of the pin holder 32.

At least one of the plurality of conductor layers 41 is in proximity to an outer surface of the ceramic holder 40. In the example of FIG. 2, of the plurality of conductor layers 41, an uppermost conductor layer 41 is in proximity to the upper surface 40A of the ceramic holder 40, and a lowermost conductor layer 41 is in proximity to the lower surface 40B of the ceramic holder 40. Therefore, heat received by the ceramic holder 40 can be efficiently dissipated to the outside from at least one of the upper surface 40A and the lower surface 40B.

Although a thickness of the lowermost ceramic layer under the lowermost conductor layer 41 is preferably thin in view of thermal conductivity, the thickness of the lowermost ceramic layer may be set to provide electrical insulation between the pogo pin 35 and the wiring board 10 via the lowermost ceramic layer. Similarly, the thickness of the uppermost ceramic layer above the uppermost conductor layer 41 may be set to provide electrical insulation between the pogo pin 35 and the main board 20 via the uppermost ceramic layer.

The conductor layer 41 is formed of the same conductor material as the conductive path (not illustrated) formed in the ceramic plate 102 of the wiring board 10 in FIG. 1. For example, if the conductive path of the ceramic plate 102 is formed of copper (Cu), the conductor layer 41 is also formed of copper (Cu). Thereby, a configuration of the pin holder 32 (conductor +ceramics) becomes similar to that of the wiring board 10 (conductor +ceramics), and thus the pin holder 32 and the wiring board 10 can undergo thermal expansion and thermal contraction in the same manner.

Next, a method for manufacturing the probe card 1 having the configuration described above will be described. The method for manufacturing the probe card 1 includes the following steps of forming the ceramic holder 40.

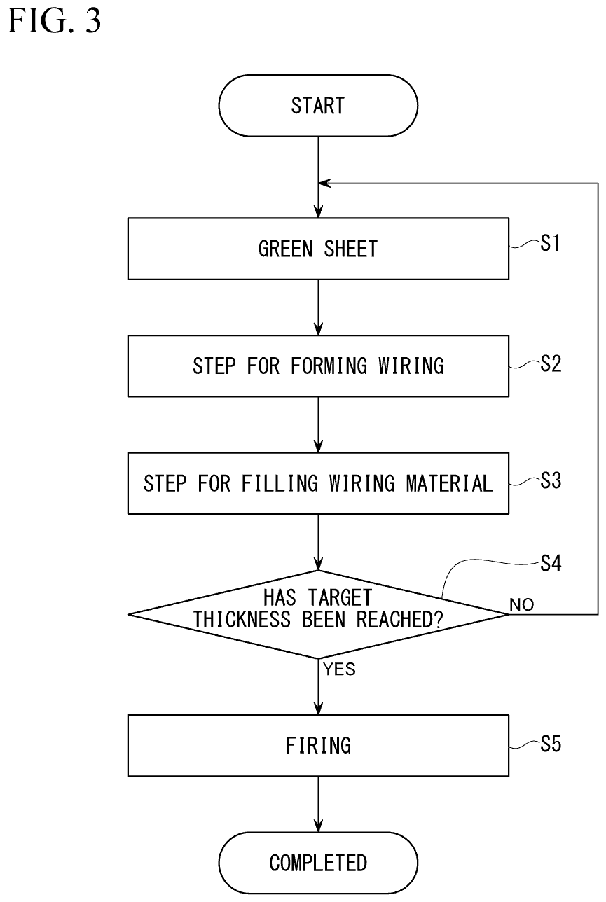

FIG. 3 is a flowchart of a step for forming the ceramic holder 40 according to the first embodiment. As shown in FIG. 3, in the step of forming the ceramic holder 40, the ceramic holder 40 is formed by laminating a plurality of green sheets and firing the laminated green sheets. Specifically, first, green sheets are prepared (step S1).

A green sheet is one formed by kneading ceramic raw material powder and a binder and uniformly forming the mixture into a thin sheet, and has flexibility before firing. The green sheet can be fired simultaneously with the conductor layer 41 in a later step. Further, in step S1, the guide hole 33 and the insertion hole 34 may be formed in advance in the green sheet, or the guide hole 33 and the insertion hole 34 may be formed after firing (step S5).

Next, a groove (wiring groove) for forming the conductor layer 41 is formed in the green sheet (step S2). Next, a wiring material (for example, copper (Cu) paste or the like) is filled into the wiring groove (step S3). Then, the green sheets are laminated, and it is determined whether a target thickness has been reached (step S4). If the thickness of the laminate of the green sheets has not reached the target thickness, the above-described steps are repeated.

If the thickness of the laminate of the green sheets reaches the target thickness, the process proceeds to step S5, in which the laminated green sheets are fired. Thereby, the ceramic holder 40 (the pin holder 32) having the plurality of conductor layers 41 (solid patterns that are not electrically connected in a vertical direction) therein can be formed.

Further, the ceramic holder 40 can also be formed by the following steps.

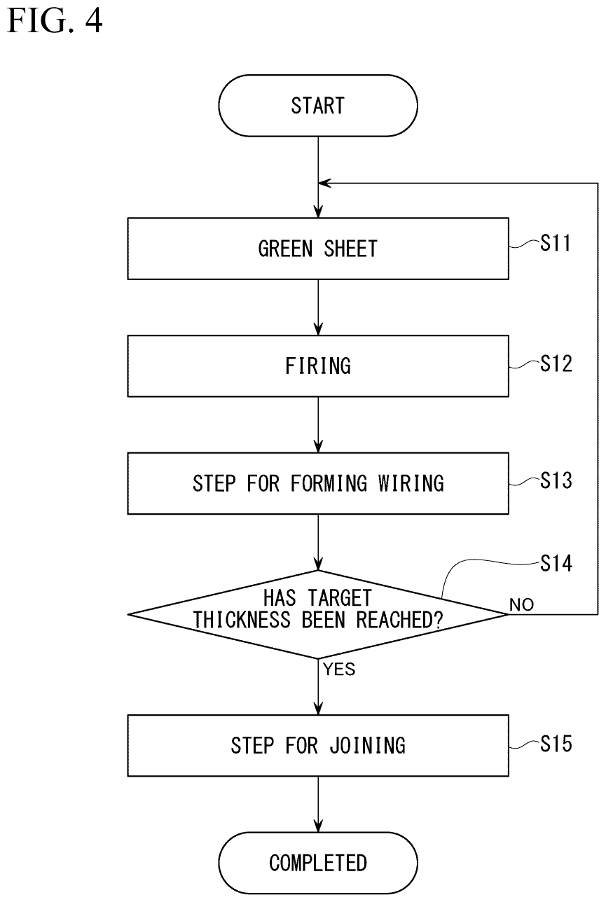

FIG. 4 is a flowchart of a step for forming the ceramic holder 40 according to one modified example of the first embodiment.

In the modified example shown in FIG. 4, first, a green sheet is prepared (step S11). Next, the green sheet is fired (step S12). That is, the green sheet is fired before the wiring (conductor layer 41) is formed.

Next, the conductor layer 41 (wiring) is formed on the fired green sheet (ceramic body) (step S13). The conductor layer 41 can be formed by, for example, patterning or the like of a conductor film using photolithography. Then, the ceramic body is laminated, and it is determined whether a target thickness has been reached (step S14). If the thickness of the ceramic laminate has not reached the target thickness, the above-described steps are repeated.

If the thickness of the ceramic laminate reaches the target thickness, the process proceeds to step S15, in which the ceramic laminates are joined. Further, the ceramic laminate can be joined via a ceramic joining material. Thereby, the ceramic holder 40 (the pin holder 32) having the plurality of conductor layers 41 (solid patterns that are not electrically connected in a vertical direction) therein can be formed.

As described above, the probe card 1 of the present embodiment includes the main board 20, the wiring board 10 having the plurality of probes 11, the plurality of pogo pins 31 electrically connecting the main board 20 and the wiring board 10, and the pin holder 32 disposed between the main board 20 and the wiring board 10 and having the plurality of guide holes 33 that guide the plurality of pogo pins 31, in which the pin holder 32 is formed from the ceramic holder 40 having therein the plurality of conductor layers 41 that are not electrically connected to each other. According to this configuration, since the pin holder 32 has the conductor layers 41 that are electrically non-conductive in the vertical direction inside the pin holder 32, thermal diffusivity and heat dissipation of the pin holder 32 are improved. Therefore, heat received by the pin holder 32 is quickly diffused inside the pin holder 32 and dissipated to the outside, thereby suppressing thermal contraction or thermal expansion of the pin holder 32. Therefore, displacement of the pogo pin 31 from the pad 10a due to an influence of thermal contraction or thermal expansion of the pin holder 32 is suppressed, and electrical continuity between the main board 20 and the wiring board 10 can be ensured under various temperature environments.

Also, in the present embodiment, the plurality of conductor layers 41 are formed by a solid pattern in which the openings 42 are formed at positions corresponding to the plurality of guide holes 33. According to this configuration, an area of each conductor layer 41 can be increased to improve thermal diffusivity and heat dissipation of the pin holder 32. Also, since the opening 42 is formed in a solid pattern of each conductor layer 41, it is possible to avoid electrical influence on the pogo pin 31 inserted through the guide hole 33.

Also, in the present embodiment, at least one of the plurality of conductor layers 41 is in proximity to an outer surface of the ceramic holder 40. According to this configuration, heat from the pin holder 32 can be easily released to the outside from the outer surface, and heat dissipation of the pin holder 32 can be further improved.

Also, in the present embodiment, the wiring board 10 includes the ceramic plate 102 in which a plurality of conductive paths are provided. According to this configuration, since thermal expansion coefficients of the pin holder 32 (ceramic holder 40) and the wiring board 10 including the ceramic plate 102 become close to each other, and the two undergo thermal contraction or thermal expansion in the same manner, the pogo pin 31 is less likely to be displaced from the pad 10a.

Also, in the present embodiment, the plurality of conductive paths and the plurality of conductor layers 41 are formed of the same conductor material. According to this configuration, since thermal expansion coefficients of the pin holder 32 and the wiring board 10 become even closer, and the two undergo thermal contraction or thermal expansion in the same manner, the pogo pin 31 becomes even less likely to be displaced from the pad 10a.

Also, the method for manufacturing the probe card 1 of the present embodiment is a method for manufacturing the probe card 1 including the main board 20, the wiring board 10 having the plurality of probes 11, the plurality of pogo pins 31 electrically connecting the main board 20 and the wiring board 10, and the pin holder 32 disposed between the main board 20 and the wiring board 10 and having the plurality of guide holes 33 that guide the plurality of pogo pins 31, in which the method including forming the pin holder 32 from the ceramic holder 40 having therein the plurality of conductor layers 41 that are not electrically connected to each other. According to this method, it is possible to manufacture the probe card 1 in which electrical continuity between the main board 20 and the wiring board 10 can be ensured under various temperature environments without the pogo pin 31 being displaced from the pad 10a.

Also, in the present embodiment, the ceramic holder 40 is formed by laminating the green sheets on which the conductor layers 41 are formed and firing the laminated green sheets. According to this method, it is possible to easily form the ceramic holder 40 having therein the plurality of conductor layers 41 that are not electrically connected to each other.

### Second Embodiment

Next, a second embodiment of the present invention will be described. In the following description, components the same as or equivalent to those of the above-described embodiment will be denoted by the same reference signs, and description thereof will be simplified or omitted.

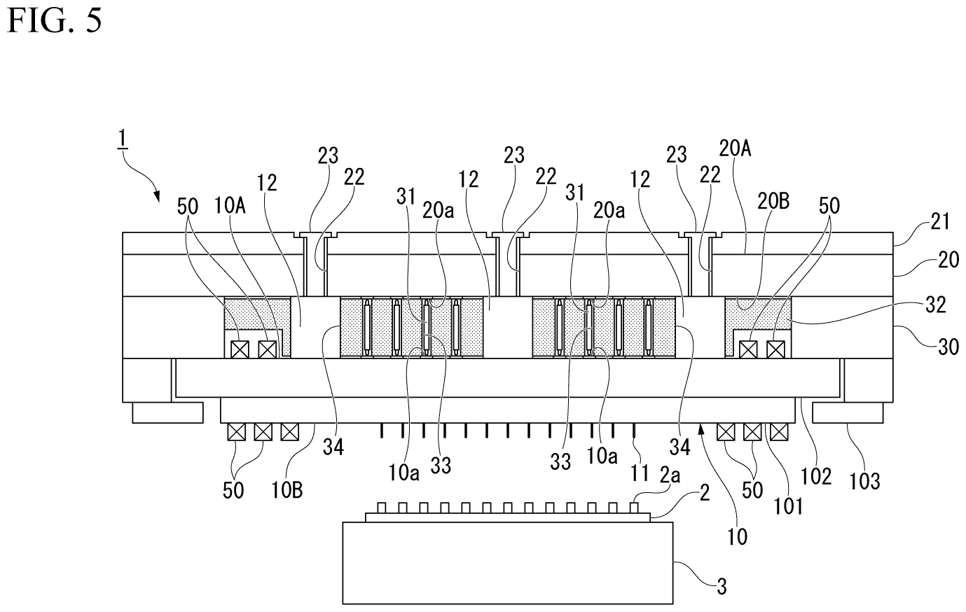

FIG. 5 is a schematic view illustrating a state in which a probe card 1 according to the second embodiment is in use. As illustrated in FIG. 5, in addition to probes 11, a plurality of electronic components 50 are mounted on a surface of a wiring board 10. Examples of the electronic components 50 include, for example, a chip capacitor. When one of the electronic components 50 fails, it is necessary to replace the electronic component 50, but if the electronic components 50 are mounted at high density, there is no space for inserting a repair tool such as a tool, torch, or soldering iron, and it is not easy to remove the electronic component 50.

Therefore, the second embodiment employs the following configuration.

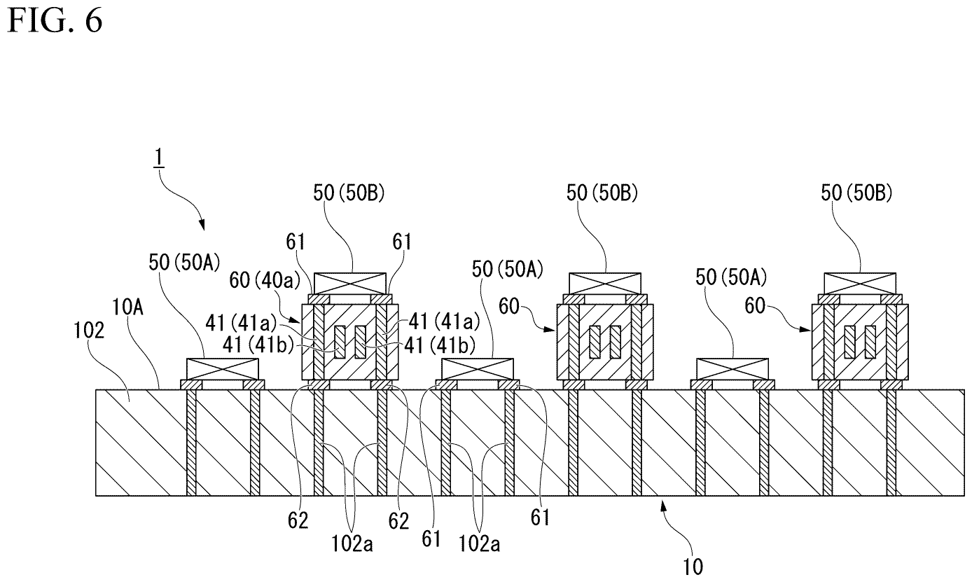

FIG. 6 is a cross-sectional configuration view of a top surface 10A side of the wiring board 10 according to the second embodiment. As illustrated in FIG. 6, the wiring board 10 includes a first electronic component 50A provided on a surface of the wiring board 10, a second electronic component 50B provided adjacent to the first electronic component 50A in a plan view, and a block piece 60 provided on the surface of the wiring board 10 and configured to dispose the second electronic component 50B at a position higher than the first electronic component 50A.

The first electronic component 50A is electrically connected to a conductive path 102a of the wiring board 10 (ceramic plate 102) via a component contact pad 61. The block piece 60 is formed from a ceramic laminate 40a having a plurality of conductor layers 41 therein. The plurality of conductor layers 41 each include a conductive pattern 41a that electrically connects the wiring board 10 and the second electronic component 50B, and a non-conductive heat dissipation pattern 41b that does not electrically connect the wiring board 10 and the second electronic component 50B.

The conductive pattern 41a is exposed on a lower surface of the block piece 60 and is electrically connected to a conductive path 102a of the wiring board 10 (ceramic plate 102) via a board contact pad 62. Also, the conductive pattern 41a is exposed on an upper surface of the block piece 60 and is electrically connected to the second electronic component 50B via the component contact pad 61. The conductive pattern 41a is provided as a pair that are spaced apart in a left-right direction, and the conductive patterns 41a extend parallel to each other in a vertical direction.

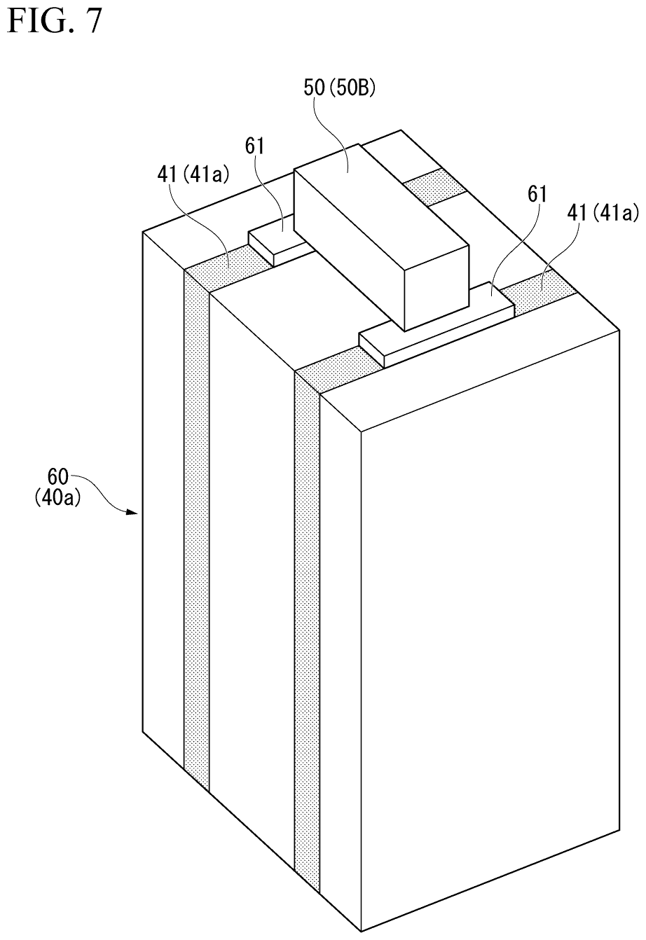

FIG. 7 is a perspective view illustrating a state in which the second electronic component 50B is attached to the block piece 60 according to the second embodiment.

As illustrated in FIG. 7, the second electronic component 50B is joined to a pair of component contact pads 61 on the upper surface of the block piece 60 via solder (not illustrated). The pair of component contact pads 61 are electrically connected to a pair of conductive patterns 41a exposed on the upper surface of the block piece 60. Further, although the pair of conductive patterns 41a illustrated in FIG. 7 are exposed not only on the upper surface and the lower surface of the block piece 60 but also on side surfaces thereof, the conductive patterns 41a need not be exposed on the side surfaces of the block piece 60.

Returning to FIG. 6, the heat dissipation pattern 41b is provided inside the block piece 60 and is not exposed on the outer surface of the block piece 60. A plurality of heat dissipation patterns 41b are provided between the pair of conductive patterns 41a. Ceramic layers are disposed between the heat dissipation pattern 41b and the pair of conductive patterns 41a to electrically insulate them from each other. Further, at least one of the heat dissipation patterns 41b may be provided outside the pair of conductive patterns 41a.

Next, a method for manufacturing the probe card 1 having the above-described configuration will be described. The method for manufacturing the probe card 1 includes the following steps of forming the block piece 60.

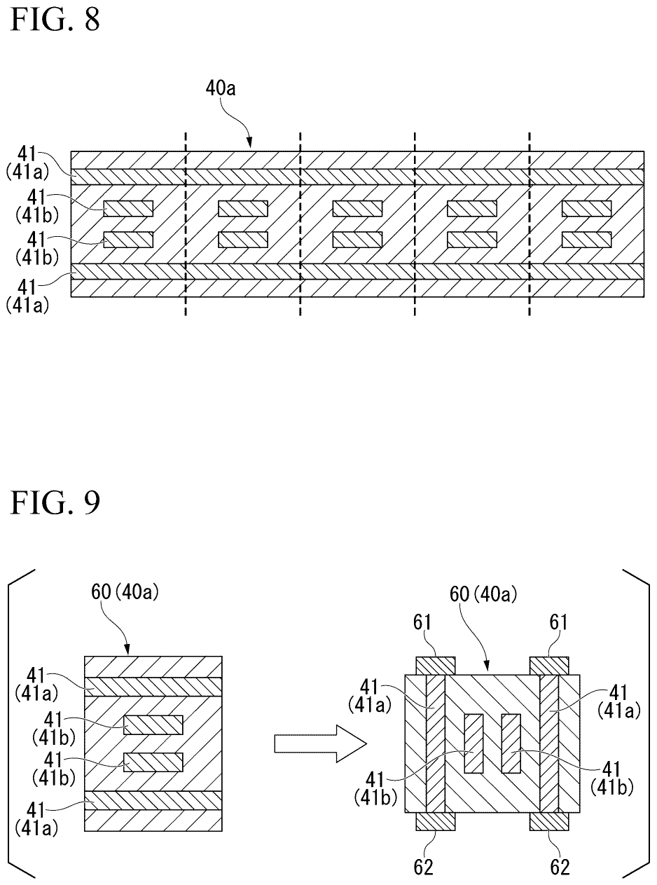

FIGS. 8 and 9 are explanatory views of steps of forming the block piece 60 according to the second embodiment.

In the step of forming the block piece 60, first, as illustrated in FIG. 8, the ceramic laminate 40a having the plurality of conductor layers 41 therein is formed. The ceramic laminate 40a can be formed by laminating green sheets through the same steps as those of the ceramic holder 40 described in the first embodiment (see FIGS. 3 and 4).

Next, the ceramic laminate 40a is cut along the dotted lines illustrated in FIG. 8 to form a plurality of block pieces 60. Next, as illustrated in FIG. 9, the cut block piece 60 is rotated by 90 degrees so that a cut surface faces in a vertical direction. Then, the component contact pads 61 are formed on the upper surface of the block piece 60, and the board contact pads 62 are formed on the lower surface of the block piece 60. Thereby, the block piece 60 having the plurality of conductor layers 41 therein can be formed.

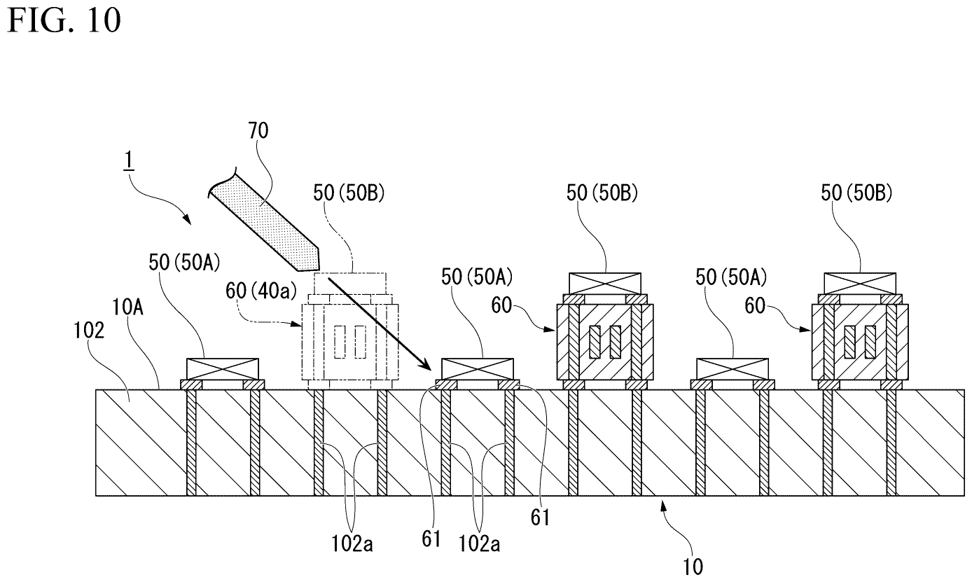

FIG. 10 is an explanatory view of a step for repairing the electronic component 50 according to the second embodiment.

As illustrated in FIG. 10, if one of the second electronic components 50B among the electronic components mounted on the wiring board 10 fails, the failed second electronic component 50B can be removed by melting a joint portion (solder) of the second electronic component 50B on the block piece 60. Since the second electronic component 50B is mounted on the block piece 60, a space into which a repair tool 70 can be inserted can be easily secured around the second electronic component 50B.

Also, if one of the first electronic components 50A among the electronic components mounted on the wiring board 10 fails, first, the block piece 60 adjacent to the first electronic component 50A is removed (indicated by the two-dot chain line in FIG. 10). Removal of the block piece 60 can be easily performed by pulling out the block piece 60 or by heating and softening a joint portion (solder) between the block piece 60 and the wiring board 10.

If it is not possible to directly heat the joint portion (solder) between the block piece 60 and the wiring board 10, the entire block piece 60 may be heated or the conductive pattern 41a may be locally heated to indirectly heat the solder, thereby facilitating removal of the block piece 60. When the block piece 60 is removed in this manner, a space into which the repair tool 70 can be easily inserted can be readily secured around the failed first electronic component 50A, thereby facilitating replacement of the failed first electronic component 50A.

As described above, the probe card 1 of the second embodiment includes a main board 20, the wiring board 10 having a plurality of probes 11 and electrically connected to the main board 20, the first electronic component 50A provided on a surface of the wiring board 10, the second electronic component 50B provided adjacent to the first electronic component 50A in a plan view, and the block piece 60 provided on the surface of the wiring board 10 and configured to dispose the second electronic component 50B at a position higher than the first electronic component 50A. According to this configuration, since the electronic component 50 can be disposed three-dimensionally by the block piece 60, removal or replacement of the electronic component 50 becomes easy even when the electronic component 50 is mounted at high density.

Also, in the present embodiment, the block piece 60 is formed from the ceramic laminate 40a having the plurality of conductor layers 41 therein. According to this configuration, when the block piece 60 is heated, the joint portion (solder) with the wiring board 10 can be softened, thereby facilitating removal of the block piece 60.

Also, in the present embodiment, the plurality of conductor layers 41 include the conductive pattern 41a that electrically connects the wiring board 10 and the second electronic component 50B, and the non-conductive heat dissipation pattern 41b that does not electrically connect the wiring board 10 and the second electronic component 50B. According to this configuration, heat received from the wiring board 10 or the second electronic component 50B can be dissipated to the outside while ensuring electrical continuity between the wiring board 10 and the second electronic component 50B.

Also, the method for manufacturing the probe card 1 of the present embodiment is a method for manufacturing the probe card 1 including the main board 20, the wiring board 10 having a plurality of probes 11 and electrically connected to the main board 20, the first electronic component 50A provided on a surface of the wiring board 10, and the second electronic component 50B provided adjacent to the first electronic component 50A in a plan view, in which the method including forming a block piece by dividing the ceramic laminate 40a having the plurality of conductor layers 41 therein, and mounting the second electronic component 50B on the block piece 60. According to this method, since the electronic component 50 can be disposed three-dimensionally by the block piece 60, removal or replacement of the electronic component 50 becomes easy even when the electronic component 50 is mounted at high density.

Also, in the present embodiment, the ceramic laminate is formed by laminating the green sheets on which the conductor layers 41 are formed and firing the laminated green sheets. According to this method, it is possible to easily form the ceramic laminate 40a having the plurality of conductor layers 41 therein.

While preferred embodiments of the present invention have been described and illustrated above, it should be understood that these are exemplary of the present invention and are not to be considered as limiting. Additions, omissions, substitutions, and other modifications can be made without departing from the scope of the present invention. Accordingly, the present invention is not to be considered as being limited by the foregoing description and is only limited by the scope of the claims.

For example, part or all of the second embodiment described above can be additionally described as follows.

### Appendix 1-1

A probe card including:
a main board;
a wiring board having a plurality of probes and electrically connected to the main board;
a first electronic component provided on a surface of the wiring board;
a second electronic component provided adjacent to the first electronic component in a plan view; and
a block piece provided on the surface of the wiring board and configured to dispose the second electronic component at a position higher than the first electronic component.

### Appendix 1-2

The probe card according to Appendix 1-1, in which the block piece is formed from a ceramic laminate having a plurality of conductor layers therein.

### Appendix 1-3

The probe card according to Appendix 1-2, in which the plurality of conductor layers include:
a conductive pattern which electrically connects the wiring board and the second electronic component; and
a non-conductive heat dissipation pattern which does not electrically connect the wiring board and the second electronic component.

### Appendix 2-1

A method for manufacturing a probe card, which is a method for manufacturing the probe card including:
a wiring board having a plurality of probes and electrically connected to the main board;
a first electronic component provided on a surface of the wiring board; and
a second electronic component provided adjacent to the first electronic component in a plan view, in which the method includes:
forming a block piece by dividing a ceramic laminate having a plurality of conductor layers therein, and mounting the second electronic component on the block piece.

### Appendix 2-2

The method for manufacturing a probe card according to Appendix 2-1, in which the ceramic laminate is formed by laminating a plurality of green sheets on which the conductor layers are formed and firing the laminated green sheets.

Also, the components in the above-described embodiment can be appropriately replaced with well-known components within a range not departing from the spirit of the present invention, and the above-described embodiment and modified example may be appropriately combined.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A probe card comprising:
a main board;
a wiring board having a plurality of probes;
a plurality of pogo pins electrically connecting the main board and the wiring board; and
a pin holder disposed between the main board and the wiring board and having a plurality of guide holes which guide the plurality of pogo pins, wherein
the pin holder is formed from a ceramic holder having therein a plurality of conductor layers which are not electrically connected to each other.

2. The probe card according to claim 1, wherein the plurality of conductor layers are formed by a solid pattern in which openings are formed at positions corresponding to the plurality of guide holes.

3. The probe card according to claim 1, wherein at least one of the plurality of conductor layers is in proximity to an outer surface of the ceramic holder.

4. The probe card according to claim 1, wherein the wiring board includes a ceramic plate in which a plurality of conductive paths are provided.

5. The probe card according to claim 4, wherein the plurality of conductive paths and the plurality of conductor layers are formed of the same conductor material.

6. A method for manufacturing a probe card, which is a method for manufacturing a probe card including:
a main board;
a wiring board having a plurality of probes;
a plurality of pogo pins electrically connecting the main board and the wiring board; and
a pin holder disposed between the main board and the wiring board and having a plurality of guide holes which guide the plurality of pogo pins, the method comprising:
forming the pin holder from a ceramic holder having therein a plurality of conductor layers which are not electrically connected to each other.

7. The method for manufacturing a probe card according to claim 6, wherein the ceramic holder is formed by laminating a plurality of green sheets on which the conductor layers are formed and firing the laminated green sheets.
